(19) United States
(12) Patent Application Publication
(10) Pub. No.: US 2015/0255737 A1
(43) Pub. Date: Sep. 10, 2015

(54) TRANSPARENT SILICONE RESIN COMPOSITION FOR NON VACUUM DEPOSITION AND BARRIER STACKS INCLUDING THE SAME

(71) Applicant: SAMSUNG SDI CO., LTD., Yongin-si (KR)

(72) Inventors: Lorenza Moro, Palo Alto, CA (US); Damien Boesch, San Jose, CA (US); Sina Maghsoodi, San Jose, CA (US)

(21) Appl. No.: 14/637,302

(22) Filed: Mar. 3, 2015

Related U.S. Application Data
(60) Provisional application No. 61/950,830, filed on Mar. 10, 2014.

(51) Int. Cl. H01L 51/00

(52) U.S. Cl. CPC H01L 51/0094; H01L 51/5253

(57) ABSTRACT

A barrier stack includes a decoupling layer comprising a siloxane polymer, and a barrier layer on the decoupling layer. The siloxane polymer is prepared from a solvent solution including a solvent, a silyl monomer and one or more silicone monomers. A method of forming the decoupling layer includes depositing (via a non-vacuum deposition technique) the solvent solution comprising the silyl monomer and the one or more silicone monomers on the substrate, and curing the curable resin composition. The siloxane polymer resulting from cure may be represented by Formula 2.

(R⁶R⁷R⁸SiO_{1/2})ₘ[(OR^{I})ₐO_{(3-a)/2}Si—Ar—SiO_{(3-b)/2}(OR^{II})_{b}]ₙ[R³SiO_{(3-d)/2}(OR^{IV})_{d}]ₚ[R¹R²SiO_{(2-c)/2}(OR^{III})_{c}]_{q}[R⁴R⁵SiO_{(2-e)/2}(OR^{III})ₑ]ᵣ Formula 2

### CROSS REFERENCE TO RELATED APPLICATION

This application claims priority to and the benefit of U.S. Provisional Application Ser. No. 61/950,830 filed on Mar. 10, 2014 and titled TRANSPARENT SILICONE RESIN COMPOSITION FOR NON VACUUM DEPOSITION AND ITS USE IN THIN FILM, the entire content of which is incorporated herein by reference.

### BACKGROUND

Many devices, such as organic light emitting devices and the like, are susceptible to degradation from the permeation of certain liquids and gases, such as water vapor and oxygen present in the environment, and other chemicals that may be used during the manufacture, handling or storage of the product. To reduce permeability to these damaging liquids, gases and chemicals, the devices are often encapsulated by incorporating a barrier stack adjacent one or both sides of the device.

In general, a barrier stack includes at least one barrier layer and at least one decoupling or smoothing layer, and can be deposited directly on the device to be protected, or may be deposited on a separate film or support, and then laminated onto the device. The decoupling layer(s) serve to provide a smooth and generally planar surface on which to deposit the barrier layer(s). The barrier layer(s) can be deposited by any of various techniques (e.g., vacuum deposition processes or atmospheric processes), but the deposition of suitably dense layers with appropriate barrier properties is typically achieved by supplying energy to the material that will ultimately form the layer. The energy supplied to the material can be thermal energy, but in many deposition processes, ionization radiation is used to increase the ion production in the plasma and/or to increase the number of ions in the evaporated material streams. The produced ions are then accelerated toward the substrate either by applying a DC or AC bias to the substrate, or by building up a potential difference between the plasma and the substrate.

The higher energy supplied by these plasma-based deposition techniques provides certain benefits. For example, higher energy deposition techniques provide higher deposition rates, which in turn increase the throughput of the deposition process. Additionally, these higher energy processes lead to the formation of denser, amorphous inorganic layers which have good barrier performance. Moreover, the higher energy deposition process creates a good interface and good adhesion between layers of the barrier stack.

However, the plasma used to deposit the barrier layers can damage the underlying decoupling layers. For example, the plasma-based techniques can cause bond breakage in the polymer structure of the decoupling layers, resulting in the creation of small volatile molecules.

The damage to the underlying decoupling layers can also lead to damage of the devices the barrier stacks are intended to protect. In particular, certain devices, such as organic light emitting devices, are sensitive to plasma, and can be damaged when a plasma based or plasma assisted deposition process is used to deposit the layers of the barrier stack. Damage caused by the plasma based or plasma assisted deposition of the layers of the barrier stack have a negative impact on the electrical and/or luminescent properties of the protected (or encapsulated) device. The type and extent of damage caused by the plasma based or plasma assisted deposition process may vary depending on the type of device, and even on the manufacturer of the device, with some devices registering significant damage and others registering little or no damage. However, some typical effects of plasma damage on organic light emitting devices include higher voltage requirements for achieving the same level of luminescence, reduced luminescence, and undesirable modifications to the properties of certain polymers.

Various polymer designs have been proposed as polymers suitable for the decoupling layers. For example, certain carbon-based monomer chemistries have been proposed in which the monomers are deposited onto a substrate, and then subsequently cured into polymer layers. However, such carbon-based layers are more susceptible to plasma damage than other chemistries, and this process requires crosslinking to occur entirely during the cure process.

Other polymer designs include the combination of silane monomers with organic acrylate monomers in an effort to increase adhesion of the polymer layer, alternative compositions for the barrier stack, and organic compositions for the polymer decoupling layer. However, these polymer designs are also susceptible to plasma damage.

### SUMMARY

According to embodiments of the present invention, silicone polymer compositions are useful in ultra-barrier structures including one or more inorganic barrier films and one or more polymer decoupling layers. The silicone polymer films in the barrier stack are formed by cross-linking smaller polymer chains. The silicone films are deposited by non-vacuum techniques and serve to decouple defects from the inorganic layers of the barrier stack.

The polymer layers (or films) are silicone based and are deposited by non-vacuum techniques. The silicone polymers have increased plasma resistance relative to strictly organic polymers. This is due to the bonding energy of the Si—O bond relative to carbon bonds. Additionally, silicone polymers may have higher transmission of O₂, while maintaining low transmission of H₂O, which may be desirable depending on the application. Silicone polymers may also withstand higher temperatures than organic polymers. Silicone polymers also have increased light transmittance compared to organic polymers.

High molecular weight (MW) silicones are especially stable. When packed together, the high MW silicone polymers create a dense network that is effective for blocking moisture permeation. However, these polymers are too heavy for evaporative deposition techniques and are best suited for direct deposition at atmospheric pressures or controlled environments. The deposition may be performed in a controlled atmosphere with low partial pressure of specific gases (H₂O and O₂ being the most common). Additionally, the total pressure may be reduced or increased to match other processes performed in line with the polymer deposition.

The silicone material includes polymer chains dispersed in solvent. After application onto the substrate, the solvent is driven off by heat and the polymers are further cross-linked by UV treatment.

### BRIEF DESCRIPTION OF THE DRAWINGS

The patent or application file contains at least one drawing executed in color. Copies of this patent or patent application publication with color drawing(s) will be provided by the office upon request and payment of the necessary fee.

These and other features and advantages of the present invention will be better understood by reference to the following detailed description when considered in conjunction with the following drawings, in which:

FIG. 1 is a schematic view of a barrier stack according to an embodiment of the present invention;

FIG. 2 is a schematic view of a barrier stack according to another embodiment of the present invention;

FIG. 3 is a schematic view of a barrier stack according to yet another embodiment of the present invention;

FIG. 4 is a graph of transmittance vs. time of the polymer layer deposited on a calcium coupon according to Synthesis Example 1; and

FIG. 5 is a photograph comparing an untreated calcium coupon (picture on left) with a calcium coupon treated with a barrier stack according to Synthesis Example 1 (picture on right) after exposure to an oven at 85° C. at 85% relative humidity for more than 1000 hours.

FIG. 6 is graph comparing the CO₂ absorption peaks in a Fourier Transform Infrared (FTIR) spectrum of the polymer layer prepared from the solvent solution of Synthesis Example 1 and a polymer layer prepared from an acrylate polymer;

FIG. 7 is a photograph of glass substrates after UV exposure prepared using the solvent solution of Synthesis Example 1 deposited by spin coating, and an oxide layer deposited by AC sputtering;

FIG. 8 is a photograph of glass substrates after UV exposure prepared using the solvent solution of Synthesis Example 1 deposited by bar coating, and an oxide layer deposited by AC sputtering; and

FIG. 9 is a photograph of glass substrates after UV exposure prepared using an acrylate polymer, and an oxide layer deposited by AC sputtering.

### DETAILED DESCRIPTION

Some types of electronic devices (e.g., OLEDs, organic solar cells, and thin film solar cells) are sensitive to moisture and oxygen, and are generally protected from them by ultra-barriers with low moisture and oxygen permeation. Such barriers can be either directly deposited on the device in a scheme called thin film encapsulation (TFE), or deposited on plastic foils that can be used as substrates or encapsulants for lamination of the devices.

It is desirable that the barrier films are thin, with thicknesses of a few microns or less. This is to ensure the best transparency for applications in which light is to be transmitted out from the device (e.g., OLEDs used for display or SSL applications) or external light is to be transmitted through the barrier to the device to generate electrical charges (e.g., in solar cells). Thin barrier films are also desired if the finished device is to be flexible, since thinner films are less prone to cracking. Conventionally, thin inorganic films have been used as barriers for these applications.

The most effective inorganic barriers are typically deposited using vacuum deposition and energetic plasma techniques (e.g., methods such as sputtering or PE-CVD). These vacuum deposition techniques use higher energy (supplied by the plasma) during deposition, which has numerous advantages. For example, these techniques typically have higher deposition rates that, in turn, increase the throughput of the process. Additionally, these techniques typically form a more dense and amorphous inorganic layer, which acts as a better barrier. Also, these techniques typically create a better interface with better adhesion between layers.

To improve barrier performance, the inorganic barrier layers are typically deposited on organic smoothing and decoupling layers. The resulting barrier stack structures are multilayer structures including multiple dyads, as described, for example, in U.S. Pat. No. 7,766,498, and U.S. Patent Publication Nos. 2012/0003484 and US2009/0169770, the entire content of all of which are incorporated herein by reference. Effective barriers can also be single inorganic layers deposited with energetic plasma on a polymeric smoothing layer deposited on an inorganic tie layer.

Unfortunately, bombardment of a polymeric surface by energetic particles can lead to the breaking of bonds and the creation of small volatile molecules originated by the damaged polymer. Such small molecules can diffuse to the sensitive encapsulated device and cause damage. This problem has been addressed, for example, by the formulation described in U.S. Pat. No. 7,766,498 (previously incorporated by reference herein). However, with increasing bombardment energy, such as that generated from use of AC cathodes rather than pulsed DC cathodes, or very low pressure in the sputtering process, the proposed solution in U.S. Pat. No. 7,766,498 (previously incorporated herein by reference) is not sufficient, and less sensitive polymeric films should be used. As such a less sensitive polymeric film, silicones are robust towards plasma damage.

Some highly stable silicone polymers are not suited for flash evaporation. This is because their high molecular weight prevents vapor-phase deposition in vacuum. These materials are better suited to non-vacuum deposition. Another reason the flash evaporation process may not be suitable is that the curing mechanism may be initiated too early when the liquid precursor is vaporized at high temperature.

According to embodiments of the present invention, the composition of a polymer decoupling layer in a multilayer barrier includes smaller silicone polymer chains (not monomers). The smaller polymer chains are synthesized in a chemistry laboratory and are dispersed in a common solvent to form a liquid (i.e., a solvent solution). The liquid (i.e., solvent solution) is then deposited on a substrate by non-vacuum methods (e.g., inkjet, spin coating, bar coating, screen printing, blade coating, etc.), and the solvent is driven off by heating/drying/evaporation. The polymer film is then further cross-linked by thermal, UV, or electron beam treatment.

Deposition of the solvent solution on the substrate can include deposition to cover the entire surface of the substrate, or a portion thereof, including a pattern on the substrate. Patterned deposition is known in the art.

The substrate of the barrier film can be any suitable material, such as, for example, a plastic foil, that can be used as a substrate for sensitive devices (e.g., OLEDs) and/or for encapsulating the same type of devices by lamination. The barrier layer can also be directly deposited on the sensitive device, which has already been fabricated on a proper substrate.

In addition to plasma resistance, other properties may be considered in selecting the composition of formulations used for ultra-barrier applications. For example, transparency in the visible spectrum for display applications, and in the UV/Vis spectrum for solar cell applications, is some such considerations. Transparency in the UV spectrum is more relevant for organic photovoltaic (OPV) devices that have higher efficiency in the UV range and that are a potential solution for continuous recharging of electronics devices indoors.

According to embodiments of the present invention, cross linking of the final polymer is high to reduce the diffusivity of moisture and other species through the polymeric layers. Such properties become more important when the number of dyads is reduced and inorganic/polymeric/inorganic structures are fabricated.

According to embodiments of the present invention, the polymer formulation enables good wetting of the substrate so as to generate uniform, smooth films. The smooth and uniform nature of the polymer layer (or film) is important as it defines the quality of the inorganic film, as well as the transparency and smoothness of the barrier. The smoothness of the barrier is important, especially when it is used as a substrate.

According to embodiments of the present invention, a silicone polymer composition comprises a mixture of short polymer chains. The mixture of short polymer chains is dispersed in a solvent to form a liquid composition that is then deposited on a substrate or other layer. The mixture of short polymer chains includes a first moiety represented by the following Chemical Formula 1a, and at least one second moiety represented by at least one of the following Chemical Formula 1b, the following Chemical Formula 1c, and the following Chemical Formula 1d.

*-Si—Ar—Si-* [Chemical Formula 1a]

R¹R²SiO_{(2-c)/2}(OR^{III})_{c} [Chemical Formula 1b]

R³SiO_{(3-d)/2}(OR^{IV})_{d} [Chemical Formula 1c]

R⁶R⁷R⁸SiO_{1/2} [Chemical Formula 1d]

In Chemical Formula 1a, Ar is a substituted or unsubstituted C6 to C30 arylene group (i.e., a divalent aryl group). In some embodiments, for example, Ar may be one of the following divalent groups:

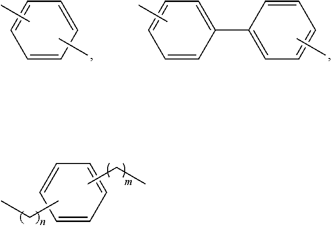

Additionally, in Chemical Formula 1a, n=1 to 10, and m=1 to 10, and * represents a group linkable to another of the polymer moieties (i.e., one of the moieties represented by Chemical Formulae 1b, 1c or 1d).

In some embodiments, the polymer chains may react to form a polysiloxane polymer represented by the following Chemical Formula 2. It is understood that the polymer does not necessarily have the structure depicted in Chemical Formula 2. Instead, the small polymer chains of Formulae 1a, 1b, 1c and 1d can react in any manner, and in any order. As such, the resulting polymer can have a random or block co-polymer structure.

(R⁶R⁷R⁸SiO_{1/2})ₘ[(OR^{I})ₐO_{(3-a)/2}Si—Ar—SiO_{(3-b)/2}(OR^{II})_{b}]ₙ[R³SiO_{(3-d)/2}(OR^{IV})_{d}]ₚ[R¹R²SiO_{(2-c)/2}(OR^{III})_{c}]_{q}[R⁴R⁵SiO_{(2-e)/2}(OR^{III})ₑ]ᵣ [Chemical Formula 2]

In Chemical Formulae 1a to 1d and 2, R^{I} to R^{IV} and R¹ to R⁸ are each independently a hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof

In some embodiments, for example, R^{I} to R^{IV} and R¹ to R⁸ are each independently hydrogen, a substituted or unsubstituted C1 to C10 alkyl group, a substituted or unsubstituted C3 to C20 cycloalkyl group, a substituted or unsubstituted C1 to C10 hydroxyalkyl group, a substituted or unsubstituted C6 to C20 aryl group, a substituted or unsubstituted C2 to C20 heteroaryl group, a substituted or unsubstituted C2 to C10 alkenyl group, a substituted or unsubstituted C1 to C10 alkoxy group, a lactone group, a substituted or unsubstituted carboxyl group, a substituted or unsubstituted glycidylether group, a hydroxyl group, or a combination thereof

In Chemical Formulae 1a to 1d and 2, a, b, and d are each independently 0 to 2, and c and e are each independently 0 to 1.

In some exemplary embodiments, Ar may be a substituted or unsubstituted C6 to C30 aryl group, 0<m<0.9, 0<n<0.2, 0≦p<0.9, 0<q<0.9 and 0≦r<0.9, and m+n+p+q+r=1.

As used herein, when a definition is not otherwise provided, the term “substituted” refers to the substitution of at least one hydrogen atom for a substituent selected from a halogen (e.g., F, Br, Cl, or I), a hydroxyl group, an alkoxy group, a nitro group, a cyano group, an amino group, an azido group, an amidino group, a hydrazino group, a hydrazono group, a carbonyl group, a carbamyl group, a thiol group, an ester group, an carboxyl group or a salt thereof, a sulfonic acid group or a salt thereof, a phosphoric acid group or a salt thereof, a C1 to C30 alkyl group, a C2 to C16 alkenyl group, a C2 to C16 alkynyl group, a C6 to C30 aryl group, a C7 to C13 arylalkyl group, a C1 to C4 oxyalkyl group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a heterocycloalkyl group, or a combination thereof

As used herein, when a definition is not otherwise provided, the term “hetero” (such as, for example, in the term “heteroaryl”) refers to a group (e.g., an aryl group) including 1 to 3 heteroatoms selected from N, O, S, and P.

In some embodiments, the polymer decoupling layer includes a polysiloxane polymer (e.g., the polymer represented by Chemical Formula 2) that is prepared by curing the solvent solution discussed above, which includes a silyl monomer having an arylene group and a silicon monomer (or monomers) dispersed in a solvent. The polysiloxane polymer is formed after deposition of the solvent solution using a non-vacuum deposition technique, and curing of the solution by, e.g., a UV, thermal or electron beam curing mechanism.

The silyl monomer having an arylene group may be represented by Chemical Formula 1a, discussed above. In some embodiments, for example, the silyl monomer may be represented by the following Chemical Formula 3.

(X¹)₃—Si—Ar—Si—(X²)₃ [Chemical Formula 3]

In Chemical Formula 3, Ar may be a substituted or unsubstituted C6 to C30 arylene group. Each of the X¹ groups is independently a C1 to C6 alkoxy group, a hydroxyl group, halogen, a carboxyl group, or a combination thereof. Each of the X² groups is independently a C1 to C6 alkoxy group, a hydroxyl group, halogen, a carboxyl group, or a combination thereof.

The silicon monomer may be at least one of the moieties represented by Chemical Formulas 1b to 1d discussed above. In some embodiments, for example, the silicon monomer may be at least one monomer (or moiety) selected from those represented by, for example, the following Chemical Formula 4, the following Chemical Formula 5, and the following Chemical Formula 6.

SiX³X⁴R¹⁴R¹⁵ [Chemical Formula 4]

SiX⁵X⁶X⁷R¹⁶ [Chemical Formula 5]

SiX⁸X⁹X¹⁰X¹¹ [Chemical Formula 6]

In Chemical Formula 4 to 6, R¹⁴ to R¹⁶ are respectively bonded to the silicon atom, and each is independently hydrogen, a substituted or unsubstituted C1 to C6 alkyl group, a substituted or unsubstituted C3 to C20 cycloalkyl group, a substituted or unsubstituted C6 to C20 aryl group, a substituted or unsubstituted C7 to C20 arylalkyl group, a substituted or unsubstituted C1 to C20 heteroalkyl group, a substituted or unsubstituted C2 to C20 heterocycloalkyl group, a substituted or unsubstituted C2 to C20 alkenyl group, a substituted or unsubstituted C2 to C20 alkynyl group, a substituted or unsubstituted C1 to C6 alkoxy group, a substituted or unsubstituted carbonyl group, a hydroxyl group, or a combination thereof X³ to X¹¹ are respectively bonded to the silicon atom, and each is independently a C1 to C6 alkoxy group, a hydroxyl group, a halogen, a carboxyl group, or a combination thereof.

The silyl monomer having an arylene group may be included in an amount of 0.01 to 20 wt %, and the silicon monomer may be included in an amount of 80 to 99.9 wt %, based on 100 wt % of the silyl monomer and the silicon monomer.

The polysiloxane polymer resulting from curing the solvent solution may have a weight average molecular weight of 800 to 100,000 g/mol, for example, 1,000 to 3,000 g/mol.

The polymer prepared from the silyl monomer and the silicon monomer can be applied to the substrate as a solvent solution, as discussed above. For example, the silyl monomer (e.g. the monomer of Chemical Formula 1a or Chemical Formula 3) and the silicon monomer(s) (e.g., the monomer(s) of Chemical Formulas 1b to 1d or 4 to 6) may be dispersed in a solvent to form a solution, which solution is then applied to the substrate. Nonlimiting examples of suitable solvents for this solvent solution include methyl isobutyl ketone (MIBK), toluene, acetone, propylene glycol methyl ether acetate (PGMEA), and the like.

The solvent solution including the silyl monomer(s) and silicon monomer(s) can then be cured to form the polymer decoupling layer (or film). The solution may be cured by any suitable curing mechanism, such as for example, thermal curing mechanisms, UV curing mechanisms, electron beam mechanisms, free radical polymerization, and the like. When thermally cured, the thermal curing can take place at a temperature of 100° C. to 300° C. in air or an inert environment. Alternatively, the solution can be cured with a free radical initiator (e.g., peroxides such as dibenzoyl peroxide (BPO), dicumyl peroxide; or azobisisobutyronitrile (AIBN)) at temperatures of 100° C. to 150° C. In another alternative, the applied solution can be UV cured with a photo-radical initiator (e.g., 2,4,6-Trimethylbenzoyl diphenylphosphineoxide (TPO) (available from CiBA Chemical now part of BASF) and/or 1-hydroxy-cyclohexyl-phenyl-ketone, IRGACURE184 (available from CiBA Chemical now part of BASF)). In some embodiments, the UV curing process may be carried out at a wavelength of 150 to 800 nm, and a power of greater than 0 mW/Cm² to 1000 mW/Cm².

As discussed generally above, in some embodiments, the solvent solution may further include a polymerization initiator. Any suitable polymerization initiator may be used, and the polymerization initiator may be selected based on the polymerization (i.e., curing) mechanism used. The polymerization mechanism is not particularly limited, and may be, for example, UV radiation, thermal cure, or electron beam treatment, but the polymerization mechanism is not limited thereto.

In embodiments in which the polymerization mechanism includes thermal cure, the polymerization initiator may include any initiator suitable for effecting cross-linking through the application of heat. Various compounds suitable for use as such an initiator are known in the art, and those of ordinary skill in the art would be capable of selecting a suitable initiator based on the desired performance and/or application of the curable resin composition. For example, any thermal initiator capable of initiating a curing reaction at a temperature of about 100° C. to about 150° C. can be used. Some nonlimiting examples of suitable such initiators include azobisisobutyronitrile, and peroxides, such as, benzoyl peroxide, dilauroyl peroxide, dicumyl peroxide.

In embodiments in which the polymerization mechanism includes UV radiation or electron beam treatment, the polymerization initiator may include a photoinitiator. Various compounds suitable for use as photoinitiators are known in the art, and those of ordinary skill in the art would be capable of selecting a suitable photoinitiator based on the curing mechanism and its parameters (e.g., the wavelength and/or power of the UV source) as well as the desired performance and/or application of the curable resin composition. For example, in some embodiments, the photoinitiator may include a compound capable of initiating a curing reaction when exposed to a UV wavelength of about 400 nm from an LED lamp or a UV wavelength of about 254 nm from a low-pressure Hg lamp. Some nonlimiting examples of suitable photoinitiators include 2,4,6-trimethylbenzoyl diphenyl phosphine oxide, hydroxy-cyclohexyl-phenyl-ketone, bis(2,4,6-trimethylbenzoyl)-phenyl phosphine oxide, 2,2-diethoxyacetophenone, and trimethylbenzophenone/methylbenzophenone. For example, in some embodiments, 2,4,6-trimethylbenzoyl diphenyl phosphine oxide, hydroxy-cyclohexyl-phenyl-ketone, and bis(2,4,6-trimethylbenzoyl)-phenyl phosphine oxide may be used when the UV source is a LED lamp emitting a wavelength of about 400 nm, and 2,2-diethoxyacetophenone, and trimethylbenzophenone/methylbenzophenone may be used when the UV source is a low pressure Hg lamp emitting a wavelength of about 254 nm.

The polymerization initiator may be present in the solvent solution in an amount of about 2 wt % to about 10 wt % based on the total weight of the curable resin composition. For example, in some embodiments, the polymerization initiator may be present in the solvent solution in an amount of about 3 wt % to about 7 wt % based on the total weight of the solvent solution. In some embodiments, the polymerization initiator may be present in an amount of about 4 wt % to about 6 wt %, for example, about 4.5 wt % based on the total weight of the solvent solution.

The solvent solution may be deposited on a substrate, or as discussed in further detail below, directly on a device (e.g., an organic light emitting device (OLED)). The solvent solution may be deposited by any suitable non-vacuum deposition technique, including, but not limited to, inkjet printing, screen printing, spin coating, blade coating, bar coating, etc. In some embodiments, for example, the solvent solution may be deposited by inkjet printing. The curable resin composition may be deposited on an entire surface of the substrate or device, or may be deposited only on select areas of the substrate or device. The substrate may be any suitable substrate, for example, a plastic foil.

The siloxane polymer films produced from the solvent solutions according to embodiments of the present invention exhibit improved resistance to plasma compared to traditional polymers used for decoupling layers in a barrier stack structure. In addition to improved plasma resistance, the polymers resulting from the solvent solutions according to embodiments of the present invention exhibit good transparency in the visible and UV/vis spectra. Moreover, the polymer layers (or films) resulting from the solvent solutions according to embodiments of the present invention exhibit good wettability of the underlying substrate (or device), enabling the manufacture of a substantially uniform, smooth film. As used herein, the term “substantially” is used as a term of approximation, and not as a term of degree, and is intended to account for inherent, standard deviations in measured or calculated values, as would be understood by those of ordinary skill in the art.

According to some embodiments of the present invention, a barrier stack includes a decoupling (or smoothing/planarization) layer and a barrier layer. In some embodiments, the barrier stack may include additional decoupling layers and additional barrier layers arranged in dyads. A dyad is a coupling of a decoupling layer and a barrier layer, and when a barrier stack includes multiple dyads, the resulting barrier stack structure includes alternating layers of decoupling layers and barrier layers such that the barrier layer of a first dyad is on the decoupling layer of the first dyad, the decoupling layer of the second dyad is on the barrier layer of the first dyad, the barrier layer of the second dyad is on the decoupling layer of the second dyad, and so on. The layers of the barrier stack can be directly deposited on a device to be encapsulated (or protected) by the barrier stack, or may be deposited on a separate substrate or support, and then laminated on the device. The decoupling layer(s) of the barrier stack serves as a planarization, decoupling and/or smoothing layer, and may include a siloxane polymer layer (or film), for example derived from the solvent solution described above. To form the decoupling layer of the barrier stack, the solvent solution is applied to the substrate (or device, or underlying barrier layer of a prior dyad), and cured, e.g., by heat, UV radiation or electron beam treatment, as discussed above. By virtue of the curing procedure, the resulting polymer layer (or film) includes a siloxane polymer including the moieties described above. For example, upon curing, the cured (or cross-linked) siloxane polymer includes moieties derived from the silyl monomer(s) (represented by Chemical Formula 1a or Chemical Formula 3 above) and the silicone monomer(s) (represented by one or more of Chemical Formulas 1b to 1d or Chemical Formulas 4 to 6 above).

The solvent solution may be deposited on the device or substrate by any suitable non-vacuum deposition technique, some nonlimiting examples of which include spin coating, ink jet printing, screen printing and spraying.

The decoupling layer can have any suitable thickness such that the layer has a substantially planar and/or smooth layer surface. As used herein, the term “substantially” is used as a term of approximation and not as a term of degree, and is intended to account for normal variations and deviations in the measurement or assessment of the planar or smooth characteristic of the decoupling layer. In some embodiments, for example, the decoupling layer has a thickness of about 100 to about 1000 nm.

According to embodiments of the present invention, the barrier stack also includes a barrier layer, which serves to prevent or reduce the permeation of damaging gases, liquids and chemicals to the encapsulated or protected device. The barrier layer is deposited on the decoupling layer, and deposition of the barrier layer may vary depending on the material used for the barrier layer. However, in general, any deposition technique and any deposition conditions can be used to deposit the barrier layer. For example, the barrier layer may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, or a combination thereof. In some embodiments, for example, the barrier layer is deposited by sputtering, for example, AC sputtering.

The material of the barrier layer is not particularly limited, and may be any material suitable for substantially preventing or reducing the permeation of damaging gases, liquids and chemicals (e.g., oxygen and water vapor) to the encapsulated or protected device. Some nonlimiting examples of suitable materials for the barrier layer include metals, metal oxides, metal nitrides, metal oxynitrides, metal carbides, metal oxyborides, and combinations thereof. Those of ordinary skill in the art would be capable of selecting a suitable metal for use in the oxides, nitrides and oxynitrides based on the desired properties of the layer. However, in some embodiments, for example, the metal may be Al, Zr, Si or Ti.

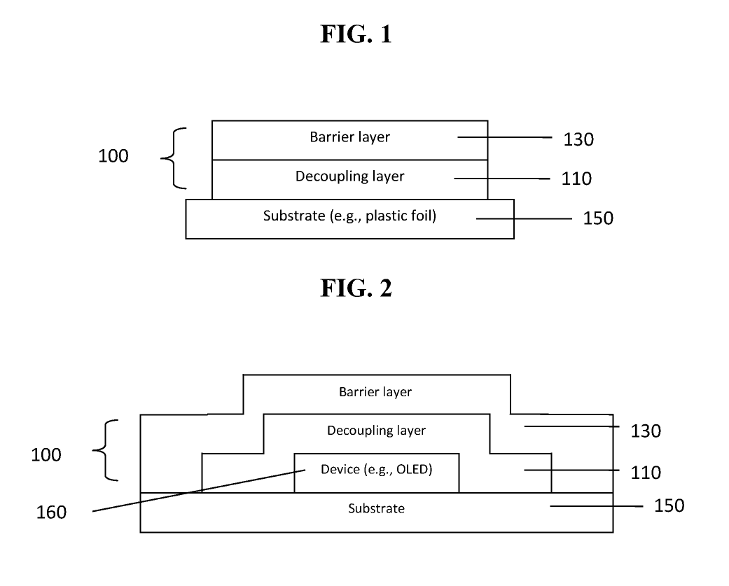

Exemplary embodiments of a barrier stack according to the present invention are illustrated in FIGS. 1 and 2. The barrier stack 100 depicted in FIG. 1 includes a decoupling layer 110 which includes a polymer cured from the solvent solution described above, and a barrier layer 130 which includes an oxide barrier layer. In FIG. 1, the barrier stack 100 is deposited on a substrate 150, for example glass. However, in FIG. 2, the barrier stack 100 is deposited directly on the device 160 to be protected, e.g., an organic light emitting device.

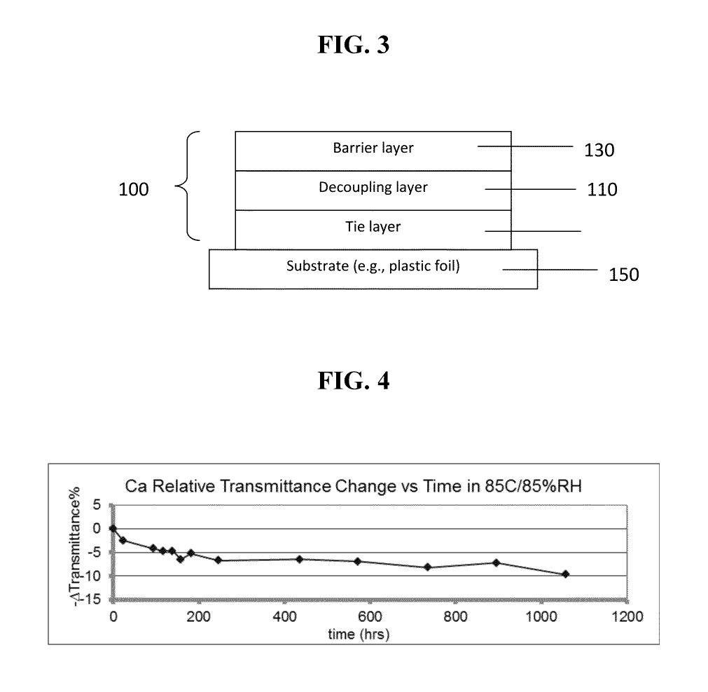

In addition to the decoupling layer 110 and the barrier layer 130, some exemplary embodiments of the barrier stack 100 can include a tie layer 140 between the decoupling layer 110 and the substrate 150 or the device 160 to be encapsulated. Although the barrier stacks are depicted in the accompanying drawings as including a tie layer 140, decoupling layer 110 and barrier layer 130, it is understood that these layers may be deposited on the substrate 150 or the device 160 in any order, and the depiction of these layers in a particular order in the drawings does not mean that the layers must be deposited in that order. Indeed, as discussed here, and depicted in FIG. 3, the tie layer 140 may be deposited on the substrate 150 or device 140 prior to deposition of the decoupling layer 110.

The tie layer 140 acts to improve adhesion between the layers of the barrier stack 100 and the substrate 150 or the device 160 to be encapsulated. The material of the tie layer 140 is not particularly limited, and can include the materials described above with respect to the barrier layer. Also, the material of the tie layer may be the same as or different from the material of the barrier layer. The material of the barrier layer is described above.

Additionally, the tie layer may be deposited on the substrate or the device to be encapsulated by any suitable technique, including, but not limited to the techniques described above with respect to the barrier layer. In some embodiments, for example, the tie layer may be deposited by sputtering, for example AC sputtering, under conditions similar to those described above for the barrier layer. Also, the thickness of the deposited tie layer is not particularly limited, and can be any thickness suitable to effect good adhesion between the decoupling layer of the barrier stack and the substrate or device to be encapsulated. In some embodiments, for example, the tie layer can have a thickness of about 20 nm to about 60 nm, for example, about 40 nm.

An exemplary embodiment of a barrier stack 100 according to embodiments of the present invention including a tie layer 140 is depicted in FIG. 3. The barrier stack 100 depicted in FIG. 3 includes a decoupling layer 110 which includes a polymer cured from the solvent solution described above, a tie layer 140 which includes an oxide layer, and a barrier layer 130 which includes an oxide barrier layer. In FIG. 3, the barrier stack 100 is deposited on a substrate 150, for example glass. However, it is understood that the barrier stack 100 can alternatively be deposited directly on the device 160, e.g., an organic light emitting device, as depicted in FIG. 2 with respect to the embodiments excluding the tie layer.

In some embodiments of the present invention, a method of making a barrier stack includes providing a substrate 150, which may be a separate substrate support or may be a device 160 for encapsulation by the barrier stack 100 (e.g., an organic light emitting device or the like). The method further includes forming a decoupling layer 110 on the substrate. The decoupling layer 110 includes a cured polymer formed from the solvent solution described above and provides a smooth and/or planar surface for the subsequent deposition of the barrier layer. As also discussed above, the decoupling layer 110 may be deposited on the device 160 or substrate 150 by any suitable non-vacuum deposition technique, including, but not limited to spin coating, ink jet printing, screen printing and spraying. For example, in some embodiments, the decoupling layer is formed on the substrate or device by ink jet printing.

The method further includes depositing a barrier layer 130 on the surface of the decoupling layer 120. The barrier layer 130 is as described above and acts as the barrier layer of the barrier stack, serving to substantially prevent or substantially reduce the permeation of damaging gases, liquids and chemicals to the underlying device. The deposition of the barrier layer 130 may vary depending on the material used for the barrier layer. However, in general, any deposition technique and any deposition conditions can be used to deposit the barrier layer. For example, the barrier layer 130 may be deposited using a vacuum process, such as sputtering, chemical vapor deposition, metalorganic chemical vapor deposition, plasma enhanced chemical vapor deposition, evaporation, sublimation, electron cyclotron resonance-plasma enhanced chemical vapor deposition, or a combination thereof. In some embodiments, however, the barrier layer 130 may be deposited by AC sputtering.

In some embodiments, the method further includes depositing a tie layer 140 between the substrate 150 (or the device 160 to be encapsulated) and the decoupling layer 110. The tie layer 140 is as described above and serves to improve adhesion between the substrate or device and the decoupling layer 110 of the barrier stack 100. The tie layer 140 may be deposited by any suitable technique, as discussed above. For example, as also discussed above, the tie layer 140 may be deposited on the substrate 150 (or the device 160 to be encapsulated) by any suitable technique. In some embodiments, for example, the tie layer 140 is deposited by AC sputtering, as discussed above.

The following examples are presented for illustrative purposes only, and do not limit the scope of embodiments of the present invention.

### Synthesis of Polysiloxane

### Synthesis Example 1

A 1 L jacketed reactor equipped with a mechanical stirrer and condenser was charged with toluene (200 g), methanol (400 g), deionized water (38.85 g, 2.16 moles) and cesium hydroxide (1.049 g, 0.0062 moles). Phenyltrimethoxysilane (99.15 g, 0.5 moles), 1,4-bis(trimethoxyethylsilyl)benzene (1.35 g, 0.0036 moles), and 3-methacryloxypropylmethyldimethoxysilane (50.87 g, 0.216 moles) were added at room temperature (25 C). The mixture was then refluxed for 2 hours and then the methanol and ethanol were distilled off. The mixture was then cooled to room temperature, neutralized with acetic acid and washed with water. The resulting polymer was dried under vacuum. Yield=89% Mw=1,600 Dalton, polydispersity (PD)=1.2.

The resulting polysiloxane structure was confirmed using H-NMR, C13-NMR and Si-NMR. The structure is shown in Chemical Formula 7 below, in which Me=methyl, Ph=phenyl, Vi=vinyl, Si=silicon, and O=oxygen.

(SiO_{3/2}—C₂H₂-Ph-C₂H₂—SiO_{3/2})_{0.05}(PhSiO_{3/2})_{0.60}(CH₃CH₂COO(CH₂)₃SiO_{1/2})_{0.305} [Chemical Formula 7]

The barrier properties of the prepared siloxane polymer were tested by using the polymer to encapsulate a calcium coupon. The results are shown in FIG. 4, which depicts relative transmittance vs. time of the encapsulated calcium coupon kept in an 85° C. oven at 85% relative humidity. The graph displays the change in transmittance of the encapsulated calcium coupon over the aging time in the damp heat oven (i.e., 85° C. and 85% RH). The calcium coupon was encapsulated by a multilayer barrier stack including sputtered inorganic barrier layers and silicone polymer decoupling layers according to embodiments of the present invention deposited by wet coating under ambient conditions. The change in transmittance corresponds to a room temperature water vapor transmission rate (WVTR) of 7.63E-7 g/m2/day after 1000 hours. The calcium test procedures are described in Nisato, et al. “P-88: Thin Film Encapsulation for OLEDs: Evaluation of Multi-Layer Barriers using the Ca Test,” SID 03 Digest, ISSN/0003-0966X/03/3401-0550, pg. 550-553 (2003)(describing the calcium test procedure) and Nisato, et al., “Evaluating High Performance Diffusion Barriers: the Calcium Test,” Proc. Asia Display, IDW01, pg. 1435 (2001) (also describing the calcium test), the entire contents of all of which are incorporated herein by reference.

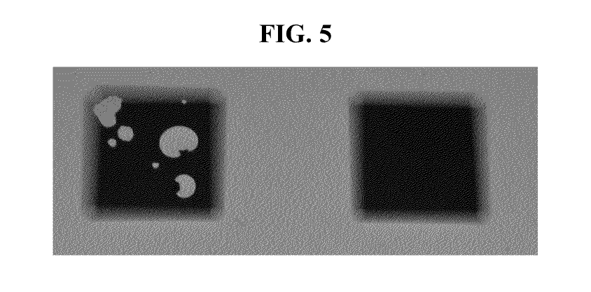

FIG. 5 is a picture of calcium coupons after more than 1000 hours accelerated aging in an over set at 85° C. and 85% relative humidity. The calcium coupon depicted on the left was not treated with a barrier stack according to an embodiment of the present invention, and shows large areas of damage from the permeation of moisture. In contrast, the calcium coupon on the right was treated with a 3 dyad barrier structure according to an embodiment of the present invention. As can be seen in the picture, the calcium coupon treated with a barrier stack according to an embodiment of the present invention had an effective barrier against moisture permeation. Indeed, the picture indicates that ultrabarrier properties were achieved on the 2×2 cm² area with no barrier defects. In this example, 3 dyads were used to account for the poor cleanliness conditions of the laboratory. However, it is understood that if suitable clean-room conditions and practices are used, the number of dyads can be reduced. Conversely, dirtier fabrication environments may require more than 3 dyads.

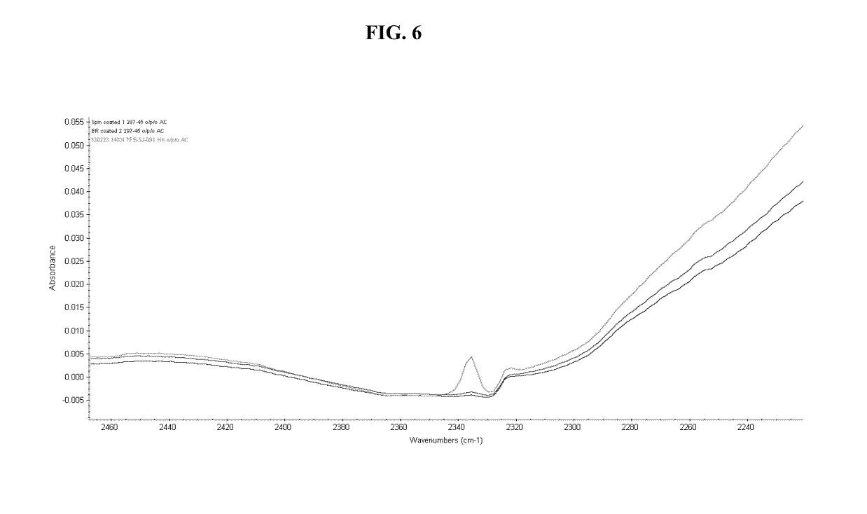

The siloxane polymer decoupling layer was evaluated for trapped CO₂ (i.e., CO₂ absorption) after cure, and compared to an acrylate polymer decoupling layer. The comparative data is shown in FIG. 6. As can be seen from this comparison, the siloxane polymer layer according to embodiments of the present invention (shown in the purple and red lines in the graph) exhibit improved CO₂ absorption rates over the acrylate polymer layer (shown in green). Specifically, the acrylate polymer layer (shown in green in the graph) exhibits a much larger CO₂ absorption peak, which is indicative of significant plasma damage.

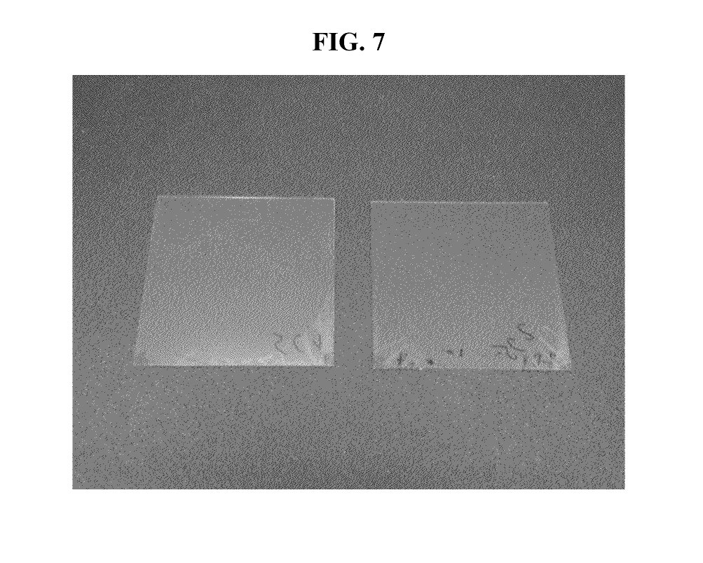

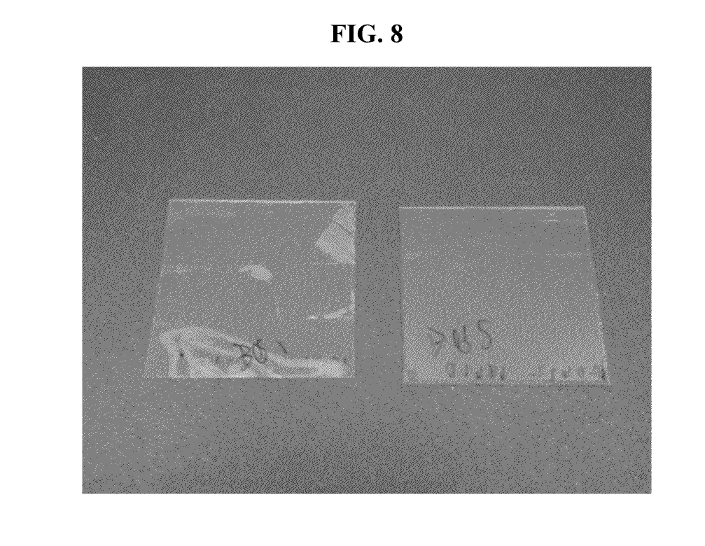

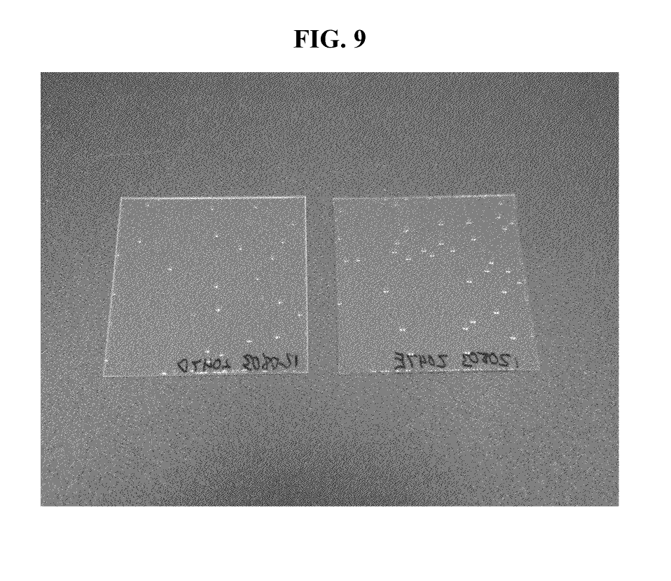

The siloxane polymer layer was also evaluated for plasma damage to the cured polymer after deposition of the barrier layer by pulsed AC sputtering. In particular, two samples were prepared by depositing the solvent solution on each of two glass substrates and cured, and then an aluminum oxide barrier layer was deposited on the first substrate over the cured polymer layer by pulsed AC sputtering. The pulsed AC sputtering was performed at a power of 4 kW, and a track speed of 75 cm/min. After deposition of the aluminum oxide layer, each substrate was placed in a UV oven and exposed to UV for 20 minutes. FIGS. 7 and 8 are photographs of the glass substrates after UV exposure, with FIG. 7 showing the glass substrates on which the polymer layer was deposited by spin coating, and FIG. 8 showing the glass substrate on which the polymer layer was deposited by bar coating. As can be seen in FIGS. 7 and 8, all substrates exhibit good plasma damage resistance. In contrast, the same test was run on an acrylate polymer layer, and those glass substrates (shown in FIG. 9) exhibited significant plasma damage (as evidenced by the high bubble density depicted in the photograph).

According to embodiments of the present invention, a siloxane polymer decoupling layer is deposited using non-vacuum deposition techniques, and registers improved resistance to plasma damage as compared to conventional polymers. The siloxane polymer layers also exhibit reduced shrinkage or swelling after cure, and a morphology that remains stable over time, even under accelerated aging conditions.

While certain exemplary embodiments of the present invention have been illustrated and described, it is understood by those of ordinary skill in the art that certain modifications and changes can be made to the described embodiments without departing from the spirit and scope of the present invention, as defined in the following claims.

What is claimed is:

1. A barrier stack, comprising:
a decoupling layer comprising a siloxane polymer represented Formula 2:
(R⁶R⁷R⁸SiO_{1/2})ₘ[(OR^{I})ₐO_{(3-a)/2}Si—Ar—SiO_{(3-b)/2}(OR^{II})_{b}]ₙ[R³SiO_{(3-d)/2}(OR^{IV})_{d}]ₚ[R¹R²SiO_{(2-c)/2}(OR^{III})_{c}]_{q}[R⁴R⁵SiO_{(2-e)/2}(OR^{III})ₑ]ᵣ Formula 2
wherein:
a, b, and d are each independently 0 to 2, and c and e are each independently 0 to 1;
0<m<0.9, 0<n<0.2, 0≦p<0.9, 0<q<0.9 and 0≦r<0.9, and m+n+p+q+r=1; and
R^{I} to R^{IV} and R¹ to R⁸ are each independently a hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof; and
a barrier layer on the decoupling layer.

2. The barrier stack of claim 1, further comprising a tie layer, wherein the decoupling layer is on the tie layer.

3. The barrier stack of claim 1, wherein R^{I} to R^{IV} and R¹ to R⁸ are each independently hydrogen, a substituted or unsubstituted C1 to C10 alkyl group, a substituted or unsubstituted C3 to C20 cycloalkyl group, a substituted or unsubstituted C1 to C10 hydroxyalkyl group, a substituted or unsubstituted C6 to C20 aryl group, a substituted or unsubstituted C2 to C20 heteroaryl group, a substituted or unsubstituted C2 to C10 alkenyl group, a substituted or unsubstituted C1 to C10 alkoxy group, a lactone group, a substituted or unsubstituted carboxyl group, a substituted or unsubstituted glycidylether group, a hydroxyl group, or a combination thereof.

4. The barrier stack of claim 1, wherein the decoupling layer comprises a cured solvent solution, the solvent solution prior to cure comprising:
a solvent;
a silyl monomer represented by Formula 3:
(X¹)₃—Si—Ar—Si—(X²)₃ Formula 3
wherein:
Ar is a substituted or unsubstituted C6 to C30 arylene group;
each X¹ group is independently a C1 to C6 alkoxy group, a hydroxyl group, halogen, a carboxyl group, or a combination thereof; and
each X² group is independently a C1 to C6 alkoxy group, a hydroxyl group, halogen, a carboxyl group, or a combination thereof; and
one or more silicone monomers selected from monomers represented by Formula 4, Formula 5, or Formula 6:
SiX³X⁴R¹⁴R¹⁵ [Formula 4]
SiX⁵X⁶X⁷R¹⁶ [Formula 5]
SiX⁸X⁹X¹⁰X¹¹ [Formula 6]
wherein:
R¹⁴ to R¹⁶ are bonded to the silicon atom, and each of R¹⁴ to R¹⁶ is independently hydrogen, a substituted or unsubstituted C1 to C6 alkyl group, a substituted or unsubstituted C3 to C20 cycloalkyl group, a substituted or unsubstituted C6 to C20 aryl group, a substituted or unsubstituted C7 to C20 arylalkyl group, a substituted or unsubstituted C1 to C20 heteroalkyl group, a substituted or unsubstituted C2 to C20 heterocycloalkyl group, a substituted or unsubstituted C2 to C20 alkenyl group, a substituted or unsubstituted C2 to C20 alkynyl group, a substituted or unsubstituted C1 to C6 alkoxy group, a substituted or unsubstituted carbonyl group, a hydroxy group, or a combination thereof; and
X³ to X¹¹ are bonded to the silicon atom, and each of X³ to X¹¹ is independently a C1 to C6 alkoxy group, a hydroxy group, a halogen, a carboxyl group, or a combination thereof.

5. The barrier stack according to claim 4, wherein the silyl monomer is present in the solvent solution in an amount of 0.01 to 20 wt % based on 100 wt % of the silyl monomer and the silicone monomer.

6. The barrier stack according to claim 4, wherein the silicone monomer is present in the solvent solution in an amount of 80 to 99.9 wt % based on 100 wt % of the silyl monomer and the silicone monomer.

7. The barrier stack of claim 1, wherein the decoupling layer comprises a cured solvent solution, the solvent solution prior to cure comprising a solvent, a first moiety represented by Formula 1a, and one or more second moieties represented by Formula 1b, Formula 1c, or Formula 1d:
*-Si—Ar—Si-* [Formula 1a]
R¹R²SiO_{(2-c)/2}(OR^{III})_{c} [Formula 1b]
R³SiO_{(3-d)/2}(OR^{IV})_{d} [Formula 1c]
R⁶R⁷R⁸SiO_{1/2} [Formula 1d]
wherein * represents a group linkable to one of the one or more second moieties.

8. A method of making a barrier stack, comprising:
forming a decoupling layer comprising a siloxane polymer over a substrate by depositing a solvent solution comprising a solvent, a silyl monomer and one or more silicone monomers on the substrate, and curing the solvent solution, the siloxane polymer comprising a compound represented by Formula 2:
(R⁶R⁷R⁸SiO_{1/2})ₘ[(OR^{I})ₐO_{(3-a)/2}Si—Ar—SiO_{(3-b)/2}(OR^{II})_{b}]ₙ[R³SiO_{(3-d)/2}(OR^{IV})_{d}]ₚ[R¹R²SiO_{(2-c)/2}(OR^{III})_{c}]_{q}[R⁴R⁵SiO_{(2-e)/2}(OR^{III})ₑ]ᵣ Formula 2
wherein:
a, b, and d are each independently 0 to 2, and c and e are each independently 0 to 1;
0<m<0.9, 0<n<0.2, 0≦p<0.9, 0<q<0.9 and 0≦r<0.9, and m+n+p+q+r=1;
Ar is a substituted or unsubstituted arylene group;
R^{I} to R^{IV} and R¹ to R⁸ are each independently a hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof; and
forming a barrier layer comprising an inorganic material over the decoupling layer.

9. The method of claim 8, wherein:
the silyl monomer silyl monomer is represented by Formula 3:
(X¹)₃—Si—Ar—Si—(X²)₃ Formula 3
wherein:
Ar is a substituted or unsubstituted C6 to C30 arylene group;
each X¹ group is independently a C1 to C6 alkoxy group, a hydroxyl group, halogen, a carboxyl group, or a combination thereof; and
each X² group is independently a C1 to C6 alkoxy group, a hydroxyl group, halogen, a carboxyl group, or a combination thereof; and
the one or more silicone monomers are selected from monomers represented by Formula 4, Formula 5, or Formula 6:
SiX³X⁴R¹⁴R¹⁵ [Formula 4]
SiX⁵X⁶X⁷R¹⁶ [Formula 5]
SiX⁸X⁹X¹⁰X¹¹ [Formula 6]
wherein:
R¹⁴ to R¹⁶ are bonded to the silicon atom, and each of R¹⁴ to R¹⁶ is independently hydrogen, a substituted or unsubstituted C1 to C6 alkyl group, a substituted or unsubstituted C3 to C20 cycloalkyl group, a substituted or unsubstituted C6 to C20 aryl group, a substituted or unsubstituted C7 to C20 arylalkyl group, a substituted or unsubstituted C1 to C20 heteroalkyl group, a substituted or unsubstituted C2 to C20 heterocycloalkyl group, a substituted or unsubstituted C2 to C20 alkenyl group, a substituted or unsubstituted C2 to C20 alkynyl group, a substituted or unsubstituted C1 to C6 alkoxy group, a substituted or unsubstituted carbonyl group, a hydroxy group, or a combination thereof; and
X³ to X¹¹ are bonded to the silicon atom, and each of X³ to X¹¹ is independently a C1 to C6 alkoxy group, a hydroxy group, a halogen, a carboxyl group, or a combination thereof.

10. A method of making a barrier stack, comprising:
forming a decoupling layer comprising a siloxane polymer over a substrate by depositing a solvent solution comprising a solvent, a first moiety and one or more second moieties on the substrate, and curing the solvent solution, the siloxane polymer comprising a compound represented by Formula 2:
(R⁶R⁷R⁸SiO_{1/2})ₘ[(OR^{I})ₐO_{(3-a)/2}Si—Ar—SiO_{(3-b)/2}(OR^{II})_{b}]ₙ[R³SiO_{(3-d)/2}(OR^{IV})_{d}]ₚ[R¹R²SiO_{(2-c)/2}(OR^{III})_{c}]_{q}[R⁴R⁵SiO_{(2-e)/2}(OR^{III})ₑ]ᵣ Formula 2
wherein:
a, b, and d are each independently 0 to 2, and c and e are each independently 0 to 1;
0<m<0.9, 0<n<0.2, 0≦p<0.9, 0<q<0.9 and 0≦r<0.9, and m+n+p+q+r=1;
Ar is a substituted or unsubstituted arylene group;
R^{I} to R^{IV} and R¹ to R⁸ are each independently a hydrogen, a substituted or unsubstituted alkyl group, a substituted or unsubstituted cycloalkyl group, a substituted or unsubstituted hydroxyalkyl group, a substituted or unsubstituted aryl group, a substituted or unsubstituted heteroaryl group, a substituted or unsubstituted alkenyl group, a substituted or unsubstituted alkoxy group, a substituted or unsubstituted lactone group, a substituted or unsubstituted carboxyl group, a substituted or unsubstituted glycidyl ether group, a hydroxyl group, or a combination thereof; and forming a barrier layer comprising an inorganic material over the decoupling layer.

11. The method of claim 10, wherein the first moiety is represented by Formula 1a, and the one or more second moieties are represented by Formula 1b, Formula 1c, or Formula 1d:
*-Si—Ar—Si—* [Formula 1a]
R¹R²SiO_{(2-c)/2}(OR^{III})_{c} [Formula 1b]
R³SiO_{(3-d)/2}(OR^{IV})_{d} [Formula 1c]
R⁶R⁷R⁸SiO_{1/2} [Formula 1d]
wherein * represents a group linkable to one of the one or more second moieties.

12. The method of claim 8, further comprising forming a tie layer between the substrate and the decoupling layer.

13. The method of claim 8, wherein the depositing the solvent solution on the substrate comprises a non-vacuum deposition technique.

14. The method of claim 8, wherein the curing the solvent solution comprises thermal curing, UV radiation, or electron beam treatment.

15. The method of claim 8, wherein the solvent solution further comprises a polymerization initiator.

16. The method of claim 10, further comprising forming a tie layer between the substrate and the decoupling layer.

17. The method of claim 10, wherein the depositing the solvent solution on the substrate comprises a non-vacuum deposition technique.

18. The method of claim 10, wherein the curing the solvent solution comprises thermal curing, UV radiation, or electron beam treatment.

19. The method of claim 10, wherein the solvent solution further comprises a polymerization initiator.
